(19) United States
(12) Patent Application Publication
(10) Pub. No.: US 2026/0001425 A1
(43) Pub. Date: Jan. 1, 2026

(54) METHODS OF INSTALLING AN ELECTRICAL OUTLET FOR CHARGING AN ELECTRIC VEHICLE AT A CURB, TRANSFER MODULE AND POWER SUPPLY INSTALLATION

(71) Applicant: ADDEL AB, Stockholm (SE)

(72) Inventor: Per RANCH, Sorunda (SE)

(21) Appl. No.: 18/879,277

(22) PCT Filed: Jun. 29, 2023
(86) PCT No.: PCT/EP2023/067916

§ 371 Date: Dec. 27, 2024

(30) Foreign Application Priority Data
Jun. 30, 2022 (EP) 2230214-5
Feb. 3, 2023 (EP) 2350103-4

(51) Int. Cl. B60L 53/31; B60L 53/16; B60L 53/30; E01C 15/00; H05K 5/02; H05K 5/04

(52) U.S. Cl. CPC B60L 53/31; B60L 53/16; B60L 53/32; E01C 15/00; H05K 5/0247; H05K 5/04; E01C 2201/04

(57) ABSTRACT

A method of installing an electrical outlet for charging an electric vehicle at a curb, wherein the curb is spaced by a sidewalk from a power supply at a house façade, comprises providing the power supply at the house façade, providing the outlet at the curb, and connecting a power supply cable from the power supply to the outlet. The sidewalk presents a surfacing formed of a plurality of pavement stones. The power supply cable is installed in a cable channel extending from the power supply to the curb and provided in a plurality of transfer modules, which have a thickness that is approximately the same as a thickness of the pavement stones and which are installed in a same plane as the pavement stones. The disclosure provides methods of installing an electrical outlet for charging an electrical vehicle at a curb, transfer modules for such installation and power supply installations.

### TECHNICAL FIELD

The present disclosure relates to methods and devices for providing a power supply to an electrical outlet at a curb.

The disclosure finds particular use for installation of curbside charging infrastructure on city streets, where power supply is available at building facades, or at lamp posts, and needs to be connected to one or more electrical outlets at the curb.

### BACKGROUND

The climate challenges and the transition to fossil-free vehicles require extensive investments in infrastructure, such as charging points for automobiles. In urban environments, installation of charging points may present a particular challenge in that there are frequently existing installations of utilities, such as water, waste water, drainage, electricity, telephony, IT infrastructure (fiber), gas and district heating. Such existing installations may be enabled by easements and thus any new installation may need to be managed both from a legally point and technically, so as not to cause disruptions.

Consequently, the process of installing a charging point may be both legally and technically complex, which may lead to increases in cost and lead time for such installations.

Moreover, the installation as such may be costly and a source of greenhouse gas emissions, in particular from excavation work. Hence, there is a need for methods of installing charging points, which reduce the complexity and cost.

WO2021250427 A1, EP2463439A1 and GB2591830A disclose the idea to install charging points in curbstones and also to install power supply cable inside such curbstones, along a curb for supplying a plurality of charging points with electric power.

However, in a scenario where the power is to be supplied from a power supply in or at a building, across e.g. a sidewalk, to such curbstone, excavation will still be needed.

### SUMMARY

Hence, it is an object of the present invention to reduce the cost of supplying electric power across an area from a power supply to an electric outlet at a curb.

The invention is defined by the appended independent claims, with embodiments being set forth in the appended dependent claims, in the following description and on the attached drawings.

According to a first aspect, there is provided a method of installing an electrical outlet for charging an electric vehicle at a curb, wherein the curb is spaced by a sidewalk from a power supply at a house façade. The method comprises providing the power supply at the house facade, providing the outlet at the curb, and connecting a power supply cable from the power supply to the outlet. The sidewalk presents a surfacing formed of a plurality of pavement stones. The power supply cable is installed in a cable channel extending from the power supply to the curb and provided in a plurality of transfer modules, which have a thickness that is approximately the same as a thickness of the pavement stones and which are installed in a same plane as the pavement stones.

The term “at a curb” should be understood such that the outlet is positioned such that it is can be accessed for charging an electric vehicle that is parked by the curb, while the sidewalk has a substantial portion that provides for free passage for pedestrians that do not have to step over a charging cable.

The exact distance between the outlet and the curb may vary depending on regulations. For example, a minimum distance may be required to prevent outlets from being damaged by e.g. snow clearing equipment and/or for allowing space for opening a vehicle door. Examples of minimum distances may be about 0.5 m, while an example of a maximum distance may be about 1.5 m.

The power supply may be an electrical cabinet, electrical junction or electrical box, which may be provided in or near a building façade. Alternatively, the power supply may be provided by a cable that connects to an electrical cabinet, electrical junction or electrical box positioned somewhere else in the building.

The power supply provided at or in a building façade, in particular at a building façade base.

The curb may be spaced from building façade by a sidewalk or plaza, 0.5-10 m, in particular about 1-5 m, about 1-2 m, about 2-3 m or about 3-5 m.

The sidewalk may be paved by a plurality of pavement stones which are installed side edge to side edge in a predetermined pattern.

By arranging the cable in a cable channel provided in modules that are as thick as the pavement stones, it is possible to install the cable by simply taking out the required number of pavement stones and replacing them with transfer modules having such cable channel. Consequently, the need for excavation is eliminated, and the risk of interference with other utilities installed in the area is reduced.

In the method, the outlet may be provided at a first position along the curb and the method may further comprise providing a second outlet at a second position along the curb, spaced from the first position, arranging a plurality of curb modules laterally outside the curb, such that the curb modules extend between the first position and the second position, and installing a second power supply cable is in a cable channel, which extends between the first position and the second position and which is provided in said curb modules.

By arranging the power supply cable in a cable channel that is formed in curb modules that are installed laterally outside the curb, and typically laterally outside existing curbstones, it is possible to retrofit a power supply along a curb without the need to remove the existing curb, which is particularly advantageous as the existing curb may include curbstones that extend vertically and/or horizontally into the ground and/or into the curb.

In the method, at least one of a length of the transfer modules and a width of the transfer modules may correspond to at least one of a length of the pavement stones and a width of the pavement stones.

In the method, the pavement stones and the transfer modules may be installed on a bed of sand, preferably compacted sand.

In the method, a lower surface, i.e. an underside, of the pavement stones may be coplanar with a lower surface of the transfer modules.

The cable channels may be spaced from both a transfer module upper surface and a transfer module lower surface.

Each transfer module may comprise at least one pair of parallel and equally long opposing side walls, wherein the cable channel is laterally spaced from a center of each of said opposing side walls.

The lateral spacing may correspond to about ⅕-⅓ of a length of each of said opposing edges.

One or more of the side walls may present a engagement portion, such as recess or through hole, which allows for an interconnection with an side wall of an immediately adjacent transfer module.

The transfer modules may be hollow.

The pavement stones may be formed of natural stone, cement or a composite thereof.

Hence, the pavement stones may be formed of e.g. granite, marble or limestone. Alternatively, the pavement stones may be formed of concrete or terrazzo.

The transfer modules may be formed of a metal material, such as iron, steel or aluminum.

The plurality of transfer modules may be installed in a row.

Alternatively, or as a supplement, the plurality of transfer modules may be installed in an aligned row, in particular straight from the façade to the outlet.

Alternatively, the plurality of transfer modules may be installed along a first direction, where immediately adjacent transfer modules are mutually offset in a second direction, which is perpendicular to the first direction.

According to a second aspect, there is provided a method of installing an electrical outlet for charging an electric vehicle at a curb, wherein the curb is spaced by a sidewalk from a house façade. The method comprises providing a power supply at a first position along the curb, providing the outlet at a second position along the curb, arranging at least two curb modules laterally outside a pre-existing curbstone, such that the curb modules extend between the first position and the second position, and installing a second power supply cable in a cable channel, which extends from the first position to the second position and which is provided in said at least two curb modules.

The power supply may be provided from a house façade, as described above, from one or more lamp posts.

According to a third aspect, there is provided a transfer module, comprising a lower part having a bottom and at least two side walls, extending essentially perpendicular from respective edge portions of the bottom, so as to define an upwardly open receptacle, and an upper part, which is connectable to the lower part and which is sized and adapted to cover the receptacle. The lower part presents at least one laterally open opening, which is sized and adapted for receiving a power cable.

The opening may be large enough to allow easy passage of such cables as are needed for supplying power for charging an electric vehicle, and which may additionally be installed in a protective sleeve. Hence, the opening should have a minimum dimension of at least about 2 cm, preferably 3 cm. in particular, the opening may extend vertically all the way from the lower part bottom to a lower edge of the upper part.

The lower part may in particular present at least two openings, formed in opposite side walls, said openings being aligned along a direction which is parallel with a side wall extending between said opposite side walls.

Such a transfer module is particularly useful in the methods described above, since it allows for the provision of a cable channel inside a surface covering.

The transfer may further comprise a fastening device, for releasably fastening the upper part to the lower part.

At least one of the side walls may comprise an engagement portion, for releasably interconnecting the lower part to another, identical or similar, lower part. At least one of the side walls may have a flange provided at a distal portion of the side wall.

The lower part may further comprise a protrusion arranged approximately centrally in the receptacle, for interaction with the upper part.

The upper part may have an upper surface and a lower surface, wherein the upper surface is provided with an anti-slip pattern.

The anti-slip pattern may be formed as a relief pattern and/or as an inverted relief.

The transfer module may have a total thickness, when the upper part is connected to the lower part, which thickness is the same as a standard thickness of a pavement stone of concrete or natural stone.

Examples of standard thicknesses may be about 2 ⅜ inch, about 3 ⅛ inch, or about 1 ¼ inch, when expressed as US customary units. For metric units, the standard thickness may be about 3 cm, about 4 cm, about 5 cm, about 6 cm, about 7 cm, or about 8 cm.

The transfer module may be rectangular and have a greatest length which is the same as a standard length of a pavement stone of concrete or natural stone. Such standard length may be 35, 40, 50 or 60 cm.

The transfer modules may be square. Square modules may measure about 35×35 cm, about 40×40 cm, about 50×50 cm, or about 60×60 cm.

The transfer module may have a width that is about ½ said greatest length, about ⅓ said greatest length or about ¼ said greatest length. The transfer modules may be rectangular. Rectangular modules may measure about 35×17.5 cm, about 40×20 cm, about 50×25 cm, or about 60×30 cm.

In the transfer module, one of said side walls may extend to an end of a first edge of the bottom that is associated with said one of said side walls, and another one of said side walls, which is associated with a second edge of the bottom that is perpendicular to said first edge, may be spaced from said one of said side walls, such that the side walls do not meet at a corner portion of the bottom. By avoiding side walls that meet at corner portions of the bottom, production of the lower part can be facilitated.

According to a fourth aspect, there is provided a power supply installation, comprising an electrical outlet for charging an electric vehicle, a power supply, and a plurality of transfer modules as described above, arranged coplanarly with a surfacing covering an area, and a cable arranged in a cable channel provided in said transfer modules and extending from the power supply to the electrical outlet. The area may be a sidewalk, a street, a plaza or any other type of open area that would be covered with a surfacing in a paved area.

According to a fifth aspect, there is provided a method of installing an electrical outlet for charging an electric vehicle at a surface having a surfacing, the method comprising providing at least two transfer modules as described above, removing the surfacing in an area having a width corresponding to a transfer module width and a length corresponding to a distance from a power source to the outlet, and arranging the transfer modules in said area, such that the openings of the transfer modules align to form a cable channel.

In the method, the surfacing may be formed of a plurality of pavement stones, said removing comprises removing pavement stones to be replaced by the transfer modules, and said arranging comprises arranging the transfer modules coplanarly with the pavement stones.

In the method, the surfacing may be an in-situ formed surfacing, such as asphalt or concrete, and said removing comprises cutting or milling away the surfacing in the area.

The method may further comprise at least one of adapting a sublayer of the surfacing, and applying a compound to reduce or seal joints between the transfer modules and their surrounding surfacing.

According to a sixth aspect, there is provided a method of installing an electrical outlet for charging an electric vehicle at a surface that is covered by a plurality of pavement stones, the method comprising providing at least two transfer module lower parts, each having a bottom and at least two side walls, extending essentially perpendicular from respective edge portions of the bottom, so as to define an upwardly open receptacle, arranging the lower parts side by side in a common plane, interconnecting said first and second lower parts, providing an extended transfer module upper part, which is sized and adapted to cover both said interconnected first and second lower parts, arranging said extended transfer module upper part on said first and second lower parts, and mounting the electrical outlet on the extended transfer module, optionally on a pole extending vertically from an upwardly exposed surface of the extended transfer module.

In the method, said first and second lower parts may be arranged such that a first side wall of a first one of the lower parts is positioned adjacent a second side wall of a second one of the lower parts, and wherein said interconnecting comprises causing a fastener to engage said first and second side walls.

The method may further comprise providing at least one third lower part, and interconnecting the third lower part to at least one of the first and second lower parts, wherein said extended transfer module upper part covers also said third lower part.

According to a seventh aspect, there is provided a connecting element, for interconnecting a pair of transfer modules as described above, comprising an element body, the element body presenting a pair of opposing side surfaces, and a first groove formed in a first one of the side surfaces, a second groove formed in a second one of the side surfaces, wherein the first and second grooves present a respective length direction, which are parallel with each other. Groove depth directions may be opposite each other.

The element body may have a first direction extending between the opposing side surfaces, a second direction which extends perpendicular to the groove length direction and a third direction which is parallel with the groove length direction, and wherein an element body length is greater along the first direction than along at least one of the second and third directions.

The element body may present a cable-channel-forming through hole along the second direction.

According to an eighth aspect, there is provided a method of interconnecting a pair of transfer modules, comprising providing a pair of transfer modules, each comprising a lower part having a bottom and at least two side walls, extending essentially perpendicular from respective edge portions of the bottom, so as to define an upwardly open receptacle, wherein the lower part presents at least one laterally open opening, which is sized and adapted for receiving a power cable, positioning the lower parts of the transfer modules adjacent each other and in a common plane, such that a joint plane is formed, which is substantially vertical and parallel with the side walls, aligning the laterally open opening of a first one of the transfer modules with the laterally open opening of a second one of the transfer modules, providing a connecting element as described above, and causing a first pair of adjacent side wall edge portions to be received in the first groove, and causing a second pair of adjacent side wall edge portions to be received in the second groove, such that relative movement of the lower parts of the transfer modules is prevented in a first direction perpendicular to the joint plane and in a second direction which is horizontal and parallel with the joint plane.

The method may further comprise providing at least one spacer element, the spacer element having a spacer element body, the spacer element body presenting a pair of opposing side surfaces, and a first groove formed in a first one of the side surfaces, a second groove formed in a second one of the side surfaces, wherein the first and second grooves present a respective length direction, which are parallel with each other; causing a first further side wall edge portion to be received in the first groove, and causing a second further side wall edge portion to be received in the second groove; and arranging at least one pavement stone in said common plane and abutting said spacer element, such that a predetermined lateral spacing is provided between the lower part and the pavement stone.

### DRAWINGS

FIGS. 1a-1d schematically illustrate a scenario wherein the inventive concept finds application.

FIG. 2 schematically illustrates a first design according to the inventive concept.

FIG. 3 schematically illustrates a first version of a transfer module.

FIG. 4 schematically illustrates a second version of a transfer module.

FIG. 5 schematically illustrates a third version of a transfer module.

FIG. 6 schematically illustrates a fourth version of a transfer module.

FIG. 7 schematically illustrates a fifth version of a transfer module.

FIG. 8 schematically illustrates a connection between a pair of transfer modules.

FIG. 9 schematically illustrates a first version of an upper part for a composite base module.

FIG. 10 schematically illustrates a second version of an upper part for a composite base module.

FIG. 11 schematically illustrates a second design according to the inventive concept.

FIG. 12 schematically illustrates an exploded view of the second design.

FIG. 13 schematically illustrates an installation according to the second design.

FIG. 14 schematically illustrates a second version of the curb module installation.

FIG. 15 schematically illustrates another version of a base module lower part.

FIG. 16 schematically illustrates another version of a lower part.

FIG. 17 schematically illustrates yet another version of a lower part.

FIG. 18 schematically illustrates yet another version of an upper part for a composite base module.

FIG. 19 schematically illustrates yet another version of an upper part for a composite base module.

FIG. 20 is a schematic cross sectional view of a transfer module designed generally in accordance with FIGS. 3 and 17.

FIG. 21 is a schematic cross sectional view of a transfer module designed generally in accordance with FIGS. 4-7 and 15-16.

FIG. 22 is a schematic cross sectional view of a transfer module designed with outwardly bent flanges.

FIG. 23 is a schematic perspective view of a connecting element for mechanically connecting a pair of adjacent transfer modules.

FIGS. 24a-24d schematically illustrates a method of mechanically connecting a pair of adjacent transfer modules.

FIG. 25 is a schematic perspective view of a first alternative design of the connecting element.

FIG. 26 schematically illustrates the connecting element according to the first alternative design in a state where it mechanically connects a pair of adjacent transfer modules.

FIGS. 27a and 27b are schematic perspective views of connecting elements according to second and third alternative designs.

FIG. 28 schematically illustrates the connecting element according to the third alternative design in a state where it mechanically connects a pair of adjacent transfer modules.

FIG. 29 schematically illustrates a transfer module in the form of a “half tile”.

FIG. 30 schematically illustrates a spacer element.

FIG. 31 schematically illustrates a lower part of a transfer module installed adjacent a pavement stone.

### DETAILED DESCRIPTION

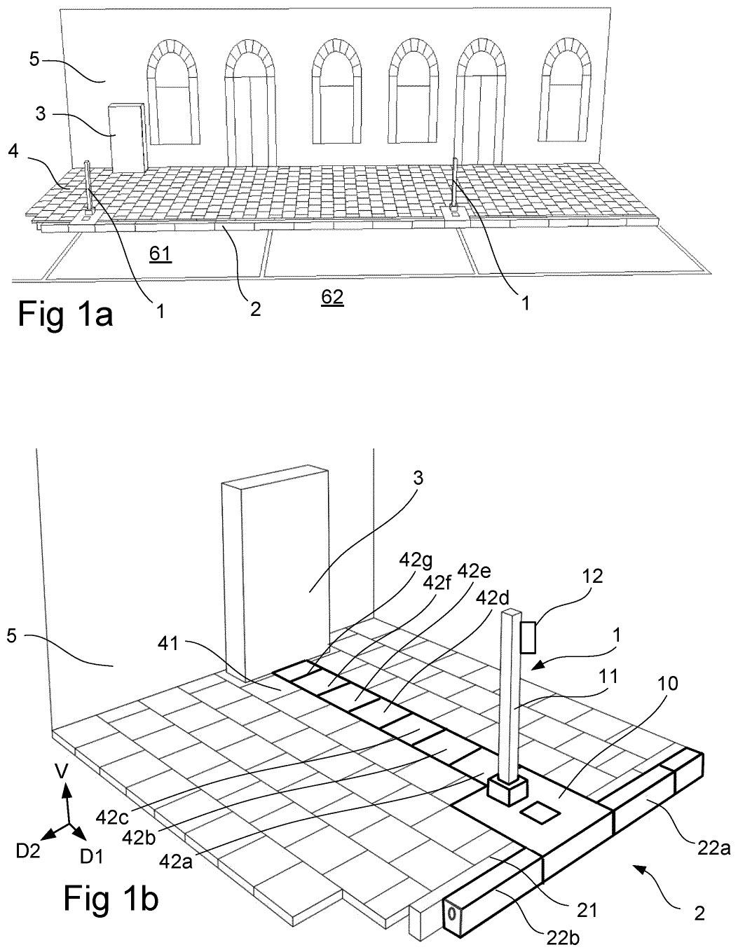

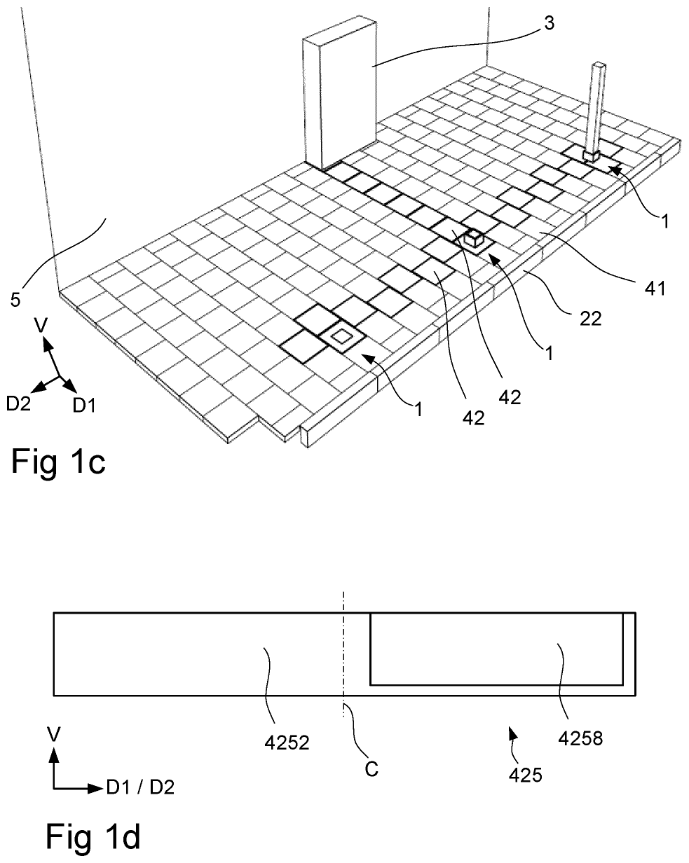

FIG. 1a schematically illustrates charging pole 1, which has been installed at a curb 2 that separates a road area 61, 62 from a sidewalk 4. The sidewalk 4 separates a building façade 5 from the curb 2. The road area 61, 62 may comprise a plurality of parking spaces 61 and one or more traffic lanes 62.

The present inventive concept aims at providing electric power to charging poles 1 that are suitably positioned for charging automobiles parked in the parking spaces 61.

Referring to FIG. 1b, the curb 2 may be formed by a plurality of curbstones 21, which are arranged along the curb, and which separate the road area 61, 62 from the sidewalk 4 area, with the sidewalk 4 typically being at a higher vertical level than the road area 61, 62. Such curbstones 21 are typically made of concrete, ceramic, clay or natural stone, in particular granite or similar stones having great hardness.

The sidewalk 4 has a surfacing formed of a plurality of pavement stones 41, which may be formed of concrete, ceramic, clay or natural stone. In the illustrated example, the pavement stones are installed in a staggered pattern, with the pavement stones 41 being aligned in a first direction D1 from the building façade towards the curb 2 and with the pavement stones 41 being offset in a second direction D2 which is perpendicular to the first direction D1.

It is understood that the transfer modules 42 disclosed herein can be installed in a wide variety of patterns, including such offset patterns as is illustrated in the drawings, but also in simple linear patterns, in herringbone patterns, diamond patterns, or the like.

The first and second directions D1, D2 are ground directions, i.e. directions which follow the surface on which the pavement stones are installed. Such directions would, in an ideal scenario, be horizontal.

A power supply 3, which here is illustrated as an electrical cabinet is arranged at the building facade 5, thus also spaced from the curb 2 by the sidewalk 4.

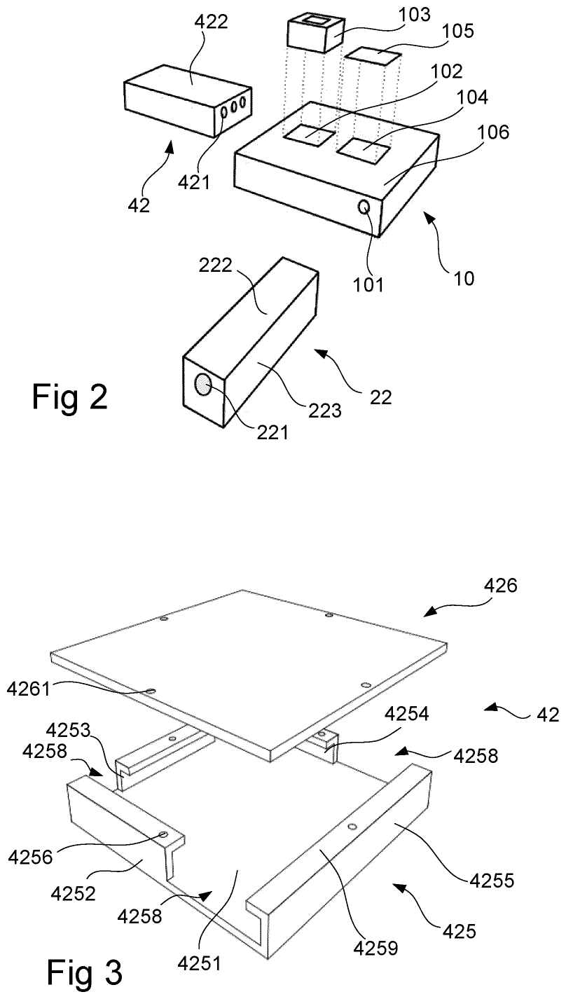

FIGS. 1b and 2 illustrate a concept of a flexible and module-based system for transferring electric power from a power source 3 positioned at the building façade 5 to the charging pole 1 at the curb and to further charging poles 1.

FIG. 1b illustrates a plurality of transfer modules 42a-42g, which have a cable channel extending inside each transfer module 42a-42g and in parallel with an upper face of the respective transfer module 42a-42g. In particular, the cable channel may, when a transfer module is positioned horizontally, be vertically spaced from both an upwardly facing surface of the transfer module and from a downwardly facing surface of the transfer module. The transfer modules 42a-42g may have the same outer format (thickness, length, width) as the pavement stones 41, such that existing pavement stones 41 can be removed and replaced by one or more transfer modules 42a-42g, whereby a cable can be installed in the cable channel. Consequently, by installing the transfer modules 42a-42g between the power source 3 and the charging pole 1, a power supply for the charging pole 1 can be provided without the need for excavation.

At the curb 2, a base module 10 may be arranged. The base module 10 encloses a cable channel, which connects to the cable channel provided by the transfer modules 42a-42g. The base module 10 forms a base on which a charging outlet 12 is mounted. The charging outlet may be mounted on e.g. a pole 11, which positions the charging outlet at a desired vertical level.

FIG. 1b also illustrates a pair of curb modules 22a, 22b, which are installed laterally outside the curb 2, such as outside existing curbstones 21, and which also enclose a cable channel that allows for installation of a cable along the curb 2, such that a single transfer module installation as illustrated in FIG. 1b can be used to supply electric power to a plurality of charging poles 1, which are arranged at spaced-apart positions along the curb 2.

The curb modules 22a, 22b may be fixed at their respective positions by adhesive, glue, cement and/or by mechanical fasteners.

FIG. 1c schematically illustrates another installation, wherein a single power supply 3 at the building façade 5 is used to supply a plurality of outlets 1, which are spaced apart from each other along the curb 2.

In particular, a first row of transfer modules 42 are installed in an aligned row along the first direction D1, which may, but need not, extend straight from the façade to the outlet 1, and in particular at a right angle to the façade 5.

A second row of transfer modules 42 are installed along a direction D2, which may be parallel with the curb 2, and/or perpendicular to the row of transfer modules 42 which extend from the facade 5 to the first outlet 1. In this second row, immediately adjacent transfer modules may be mutually offset in a second direction D1, which is perpendicular to the first direction D2.

Depending on the installation pattern of the pavement stones 41, which here is illustrated as so-called “half joints”, i.e. where the pavement stones 41 are offset about ½ of the pavement stone width, the immediately adjacent transfer modules 42 may be offset by about ¼-½ of the transfer module 42 width.

By providing the transfer modules 42 with openings for the cable, which are offset from a center of the cable module side wall, it is possible to provide a straight, or at least approximately straight, cable channel, in spite of the transfer modules 42 being laterally offset from each other.

FIG. 1d schematically illustrates a planar side view of a transfer module lower part 425. In FIG. 1d, the vertical direction V is indicated, as are the horizontal directions D1, D2.

The transfer module side wall 4252 will have a lateral center C, from which the openings 4258 are laterally offset.

In the side wall 4252 illustrated in FIG. 1d, the side wall 4252 extends from one end of its associated edge and past the lateral center C. The opening 4258 may then extend from the opposite end of the associated edge and almost to the lateral center. In particular, the opening may extend over about 25-45% of a length of the associated edge.

Referring to FIG. 2, there is illustrated a transfer module 42 with three cable channels 421 that extend from one side face to another, opposite, side face, and in parallel with a module wear face 422 of the transfer module 42.

The transfer module 42 is formed as a rectangular block, with four side walls, an upwardly facing module wear face 422 and a downwardly facing module back face, opposite the module wear face 422. The module wear face 422 would typically form the surface which is exposed when the transfer module 42 is installed. Hence, on a horizontal installation area, the module wear face 422 would be horizontally oriented and the side walls would each be vertically oriented.

The curb modules 22 would typically be formed with an upper face, 222, a front face 223 and a cable channel 221 extending along a direction that is parallel with both the front upper face 222 and the front face 223.

It is understood that the upper face 222 and/or the front face 223 may, when the curb module is arranged on a horizontal surface, be inclined with respect to a horizontal, or vertical, plane, respectively.

The curb module 22 may be formed with a rear face, opposite the front face 223, that is shaped and adapted to correspond to, and/or receive, the shape of an existing curbstone 21.

The transfer modules 42, 42a-42g and/or the curb modules 22, 22a, 22b may preferably be formed of concrete, rubber, cast iron or other suitable material.

The base module 10 may be formed with one or more openings 102, 104 provided in an upper part 106 of the base module 10. Such openings may provide for access to an inner space of the base module 10, and/or for attachment of a pole 11 or a pole adapter 103. A cover lid 105 may be provided to cover openings not used for mounting a pole 11.

The base module 10 may also comprise at least one cable channel 101. Such cable channel 101 may be provided to connect to one or more cable channels 421 provided by the transfer modules 42 to allow for power supply through transfer modules 42, 42a-42g.

A cable channel may also be provided to connect to one or more cable channels 221 provided in curb modules 22 to allow for power supply through curb modules 22, 22a, 22b to and/or from other base modules 10.

Hence, an electrical box or junction may be provided in the base module 10 for providing the desired connections from power supply to outlet 12 and/or to power supply through curb modules 22, 22a, 22b.

The base module 10 may preferably be formed of concrete or cast iron.

Transfer modules and the base modules may be installed in the same manner as normal pavement surfacing, in particular on a bed of sand, which may have been compacted. However, installation in e.g. concrete or other fixing compounds is not excluded.

FIG. 3 schematically illustrates an embodiment of a transfer module 42, which may be formed of a metal material, such as iron, steel or aluminum.

The transfer module 42 illustrated in FIG. 3 comprises a lower part 425 and an upper part 426.

The lower part 425 has a bottom 4251, which may be substantially planar and rectangular, in particular square, and four side walls 4252, 4253, 4254 and 4255, each extending substantially perpendicularly from a respective one of the edges of the bottom 4251.

One or more of the side walls 4252, 4253, 4254 and 4255 may be provided with a fastening device 4256, typically at a distal portion of the side wall 4252, 4253, 4254 and 4255. The fastening devices 4256 may comprise one or more threaded recesses or holes.

Each of the side walls 4252, 4253, 4254 and 4255 may extend along all or part of the respective edge of the bottom 4251. In the illustrated example, a first side wall 4252 and a second side wall 4254 are arranged opposite each other and extend along slightly less than ½ of a length of the respective edge. The first and second side walls 4252, 4254 may extend from a respective corner and just past a lateral center C of their associated edges, such that the remaining part of the respective edge provides an opening 4258. The first and second side walls 4252, 4254 may be aligned, such that they extend from corners at the same edge and such that their openings 4258 are aligned.

The other pair of oppositely arranged side walls 4253, 4255 are formed by a third side wall 4253, which extends over approximately ½ of its associated edge and a fourth side wall 4255 which extends along its entire associated edge.

The third side wall 4253 may be centered around the center C of its associated edge, such that openings 4258 are provided on both lateral sides of the third side wall 4253.

One or more of the side walls 4252, 4253, 4254, 4255 may be provided, at their respective distal portion with a flange 4259. Such flange 4259 may provide a means for attachment of the upper part 426. As a non-limiting example, the fastener 4256 may be provided in the flange 4259. The flange 4259 may, but need not, extend along an entire length of the side wall 4252, 4253, 4254, 4255. The flange 4259 may, but need not, be formed as a portion which extends substantially parallel with the bottom 4251. The upper part 426 may be formed as a substantially planar part having a size and shape corresponding to the bottom 4251 of the lower part 425, optionally with one or more fastening devices 4261 provided at positions corresponding to fastening devices 4256 at the lower part 425.

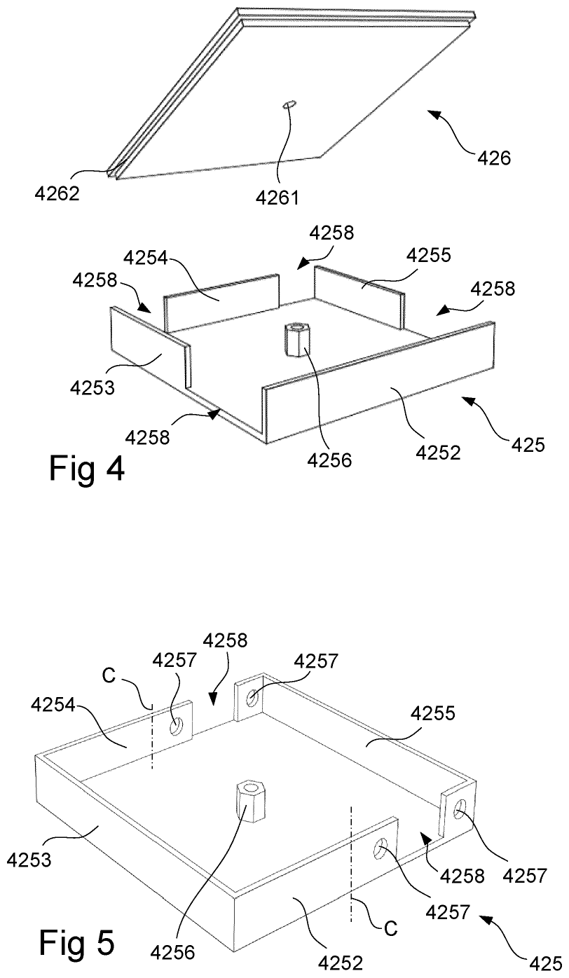

The upper part 426 may present a step 4262 (see FIGS. 4, 5) or bevel at one or more of its edges to promote fit and seal against the lower part 425.

A wear face of the upper part 426 may be provided with a pattern in relief and/or inverted relief, for providing anti-slip properties and/or for presentation of information.

Referring to FIG. 4, there is illustrated an alternative design of the transfer module 42, wherein a fastening device 4256 on the lower part 425 is provided at a central portion of the bottom 4251 and as a protrusion extending upwardly from said bottom. The fastening device 4256 may comprise a threaded hole. The protrusion may have a height that is sufficient for the upper part 426 to be supported by the protrusion when mounted to the lower part 425.

The lower part 425 illustrated in FIG. 4 has the same general layout of the side walls 4252, 4253, 4254, 4255 and openings 4258, but does not have the flanges 4259.

It is understood that a transfer module 42 may have a lower part 425 with both flanges 4259 on its side walls and a central protrusion as illustrated in FIG. 4, whereby fastening devices 4256 may be provided at flanges, as illustrated in FIG. 3 and/or at the central protrusion, as illustrated in FIG. 4.

The upper part 426 may be provided with a corresponding fastening device 4261, which may be provided as a through hole that may be countersunk at the wear surface.

Here the upper part 426 is also illustrated with a step 4262, which may be particularly advantageous in embodiments without flanges 4259, but which may also be combined with flanges 4259.

Referring to FIG. 5, there is illustrated a lower part 425 having side walls 4252, 4253, 4254, 4255 with one pair of opposing side walls 4252, 4254 being divided by openings 4258 extending over an entire side wall height.

In the example illustrated in FIG. 5, the openings 4258 are positioned opposite each other and laterally offset from a side wall center C.

Furthermore, in the lower part 425 illustrated in FIG. 5, the opposing side walls 4252, 4254 having openings 4258 are also provided with engagement portions 4257, which may take the form of recesses, hooks or through holes (as illustrated), which can be used to interconnect a pair of juxtaposed lower parts 425, e.g. in order to form a lower part of a base module 10.

The second pair of opposing side walls 4253, 4255 may extend along the entire respective associated edge, such that no opening is formed in these side walls.

The lower part 425 illustrated in FIG. 5 may be formed with flanges as illustrated in FIG. 3 and/or with a central protrusion as illustrated in FIG. 4.

The lower part illustrated in FIG. 5 may be used with the same upper part 426 as illustrated in FIG. 4, or be part of a composite base module 10.

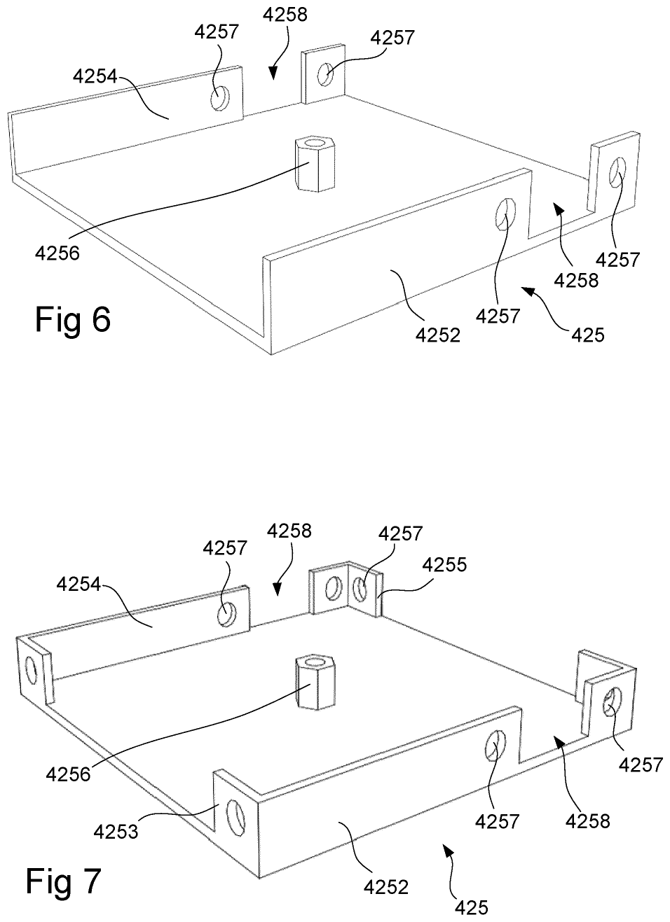

FIG. 6 illustrates an alternative lower part 425 having only one pair of opposite side walls 4252, 4254, which may be designed in accordance with the corresponding side walls of FIG. 5, while the other two opposite edges are left open, without side walls.

The lower part 425 illustrated in FIG. 6 may be formed with flanges as illustrated in FIG. 3 and/or with a central protrusion as illustrated in FIG. 4. The lower part illustrated in FIG. 6 may be used with the same upper part 426 as illustrated in FIG. 4, or be part of a composite base module 10. FIG. 7 illustrates yet another alternative lower part 425, which corresponds to the ones disclosed with reference to FIGS. 5 and 6, with the first pair of opposite side walls 4252, 4254 having the offset openings 4258. These opposite side walls 4252, 4254 also have engagement portions 4257 for connection with adjacent lower parts. The second pair of opposite side walls 4253, 4255 are entirely open, but for short wall sections 4253, 4255 at corner portions of the lower part 425, said wall sections having engagement portions 4257, such as the ones described with reference to FIG. 5.

Referring to FIG. 8, in any one of the transfer modules 42, any one of the side walls may be provided with one or more engagement portions 4257, as illustrated in FIG. 5, such that adjacent transfer modules 42 can be interconnected, e.g. by using a fastener, such as nut and bolt.

As illustrated in FIG. 8 and in FIG. 5, the engagement portions 4257 may be provided as through holes extending through the associated side wall 4252, 4254.

In FIG. 8, there is illustrated a flexible fastener in the form of a bolt 431 having a spring 432, spring washer, or the like, compressed between the wall 4252 and one of a bolt head and a nut, such that some deviation and/or movement is allowed.

When the transfer module 42 is in an assembled state, i.e. with the upper part 426 fastened to the lower part 425, an overall thickness of the transfer module may correspond to a standard thickness of a pavement stone.

The transfer modules 42 illustrated in FIGS. 3-7 may be formed by metal casting. Alternatively, the transfer modules may be formed by cutting and bending a metal sheet blank. Such sheet blank may have a wall thickness of about 5-15 mm, preferably about 7-10 mm.

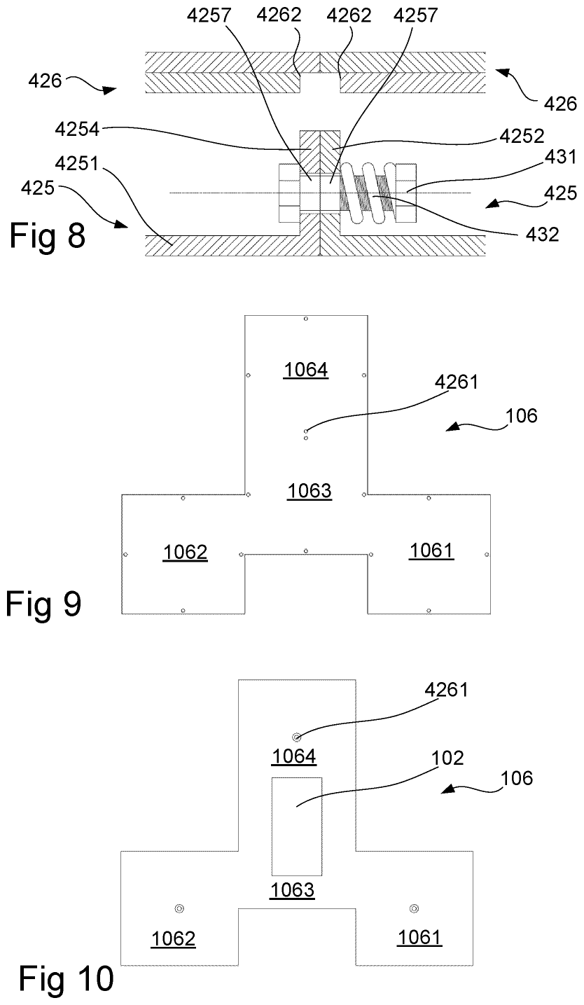

FIG. 9 illustrates a base upper part 106 that can be used for forming a base 10.

Two or more, here four, lower parts 425 are interconnected by fasteners, e.g. as illustrated in FIG. 8.

The base upper part 106 has a shape and size corresponding to the relevant number of lower parts 425, such that the base upper part 106 functions as upper part for two or more interconnected lower parts.

For example, the base upper part 106 may have a first section 1061, which corresponds to a first lower part 425 of the type illustrated in FIG. 7; a second section 1062, which corresponds to a second lower part 425 of the type illustrated in FIG. 7, which would be rotated 180 degrees in the horizontal plane and attached to the first lower part third side wall 4254 to third side wall 4254; a third section 1063, which also corresponds to a third lower part of the type illustrated in FIG. 7 and attached to the second lower part 425 first side wall 4252 to first side wall 4252; and a fourth lower part, which may also correspond to a lower part of the type illustrated in FIG. 7 and attached to the second lower part second side wall 4253 to second side wall 4253.

The version of base upper part 106 illustrated in FIG. 9 is adapted for lower parts with fastening devices corresponding to inter alia FIG. 3.

The version of base upper part 106 illustrated in FIG. 10 is adapted for lower parts with fastening devices corresponding to FIGS. 4-7.

The base upper part 106 may have one or more openings 102, 104 providing interfaces for e.g. pole or pole adapter or for a cover lid.

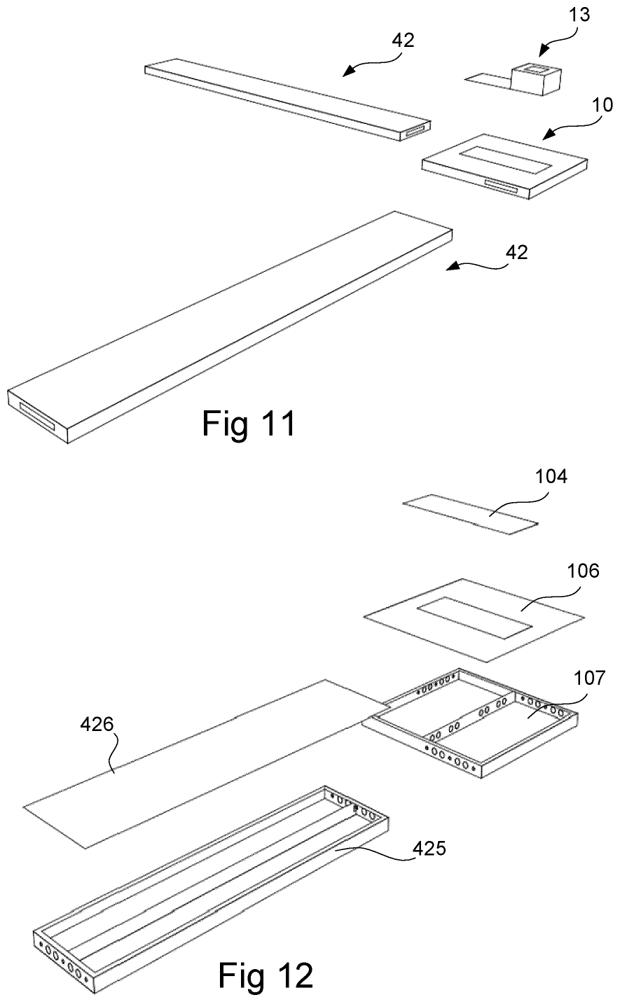

FIG. 11 illustrates an alternative design for transfer modules and base module.

According to this design, transfer modules 42 may be formed with elongate shape with a length corresponding to that of two or more pavement stones. For example, a length may be about 0.5-3 m, preferably about 1-2 m. Such length may correspond to a length and/or width of more than one pavement stone.

Alternatively, or additionally, the transfer module 42 may have a width which may correspond to a width of one pavement stone width and/or length.

The transfer module 42 has a thickness that corresponds to a pavement stone thickness, but for tolerances. Such tolerances may be less than 5%, preferably less than 1%.

Also according to this design alternative, two or more such transfer modules may be joined short side to short side to form a longer cable channel.

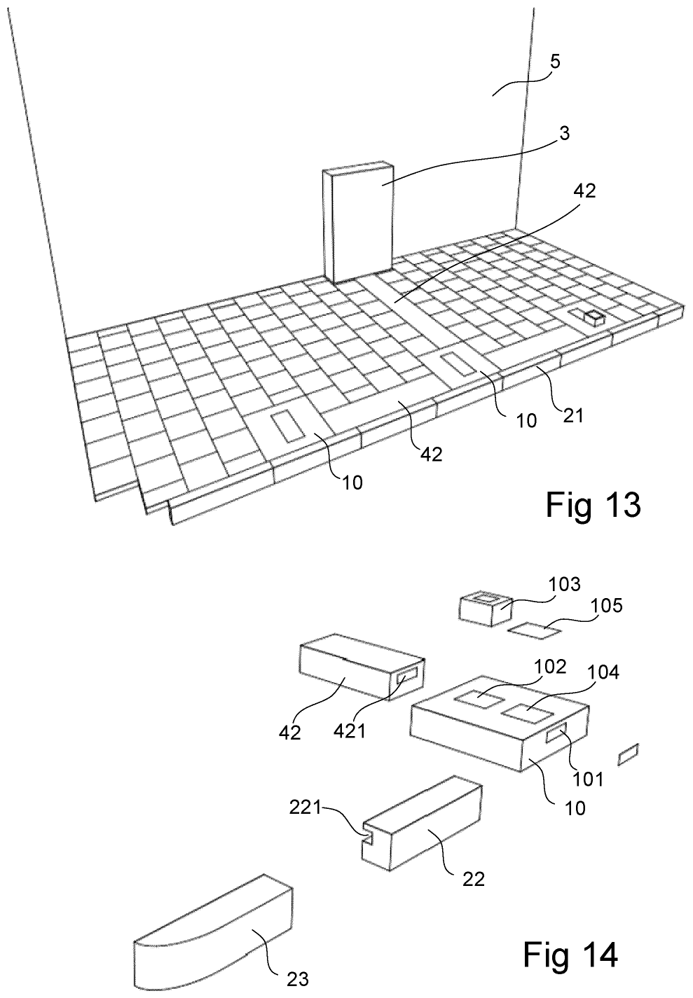

FIG. 13 also illustrates a base module 10 formed by one base module lower part 425 and one base module upper part 426.

The transfer module 42 and the base module 10 illustrated in FIG. 11 may be manufactured in the same manner as transfer modules illustrated in FIGS. 3-7, such as by casting or by bending sheet metal.

FIG. 12 illustrates an exploded view of the transfer module and base module of FIG. 11, i.e. with upper parts 426, 106 taken off.

As can be seen, the transfer module lower part 425 may have an internal longitudinal wall, which may extend along a longitudinal direction of the transfer module lower part 425, so as to divide it into two or more channels.

The internal longitudinal wall may provide additional support for the upper part 426.

The short side walls may have openings for receiving one or more cables. Moreover, the short side walls may have connection devices, which may be formed in accordance with what was described above.

Similarly, the base module lower part 107 may be divided by an internal wall into two or more subspaces.

The base module lower part 107 may have openings at one or more side walls for receiving one or more cables.

Similarly to the transfer module lower part, the base module lower part 107 may have connection devices at one or more side walls.

In the illustrated example, the base module upper part 106 has a horizontal extent corresponding to that of base module lower part 107.

FIG. 13 illustrates an installation of the transfer module and base module in FIGS. 11-12.

As can be seen in FIG. 13, a single transfer module 42 extends from the building facade 5 to the curb 2, however, this transfer module 42 may be formed by two or more interconnected transfer modules 42.

As can also be seen in FIG. 13, there is a first base module 10 installed at the curb 2 perpedicularly from the power supply 3 at the building façade 5. An additional transfer module 42 extends along the curb 2 in order to provide a cable channel to a second base module 10.

Each of the base modules may support one or more electrical outlets. Further transfer modules and further base modules may be provided along a curb 2.

A first connection from the power supply 3 to the first base module 10 is thus provided through one or more transfer modules 42 extending from the building façade 5 to the curb 2.

A second connection from the power supply 3 or from the first base module 10 to the second base module 10 is provided through one or more transfer modules 42 extending along the curb 2.

Curbstones 21 may be provided laterally outside transfer module(s) 42 extending along curb 2.

FIG. 14 illustrates an alternative curb module installation.

This installation includes one or more transfer modules 42 formed in accordance with any of the alternatives disclosed above.

Similarly, a base module 10 has one or more openings 101 in side faces for interconnection with other base module or for interconnection with transfer module 42. This base module may also be formed in accordance with any of the alternatives disclosed above.

The base module 10 may have one or more openings 101 in a side wall facing laterally from the curb for interconnection with a curb module channel 221 formed in one or more curb modules 22.

Hence, instead of installing a cable in a channel along the curb 2 formed in the pavement surface, the cable may be installed in a channel extending in one or more curb modules 22.

The system illustrated in FIG. 14 may further comprise a curb end module 23, which may also include a channel (not shown). The curb end module 23 may have tapering cross section as seen in a plane view from above.

While the concepts above have been illustrated with reference to a cable channel being provided in transfer modules that are coplanarly arranged with a surfacing layer formed of pavement stones, it is understood that the transfer modules, and the installation schemes disclosed herein can be applied also to areas having an in-situ formed surfacing, such as concrete, asphalt, terrazzo, or the like. In such cases, an area of the surfacing will need to be cut, such as sawed or milled, away to provide a trench having a width that allows installation of the transfer modules 42. As an in-situ formed surfacing may have varying, too thick or too thin, thickness, it may be desirable to adapt a sub-layer, which may be sand, gravel, pebbles or macadam, such that the trench has a depth that corresponds to the thickness of the transfer modules.

Moreover, it may be desirable to fill any gaps between the transfer modules and the surrounding surfacing. Such filling may take the form of applying sand, concrete, bitumen or other type of sealing compound suitable for sealing road surfaces.

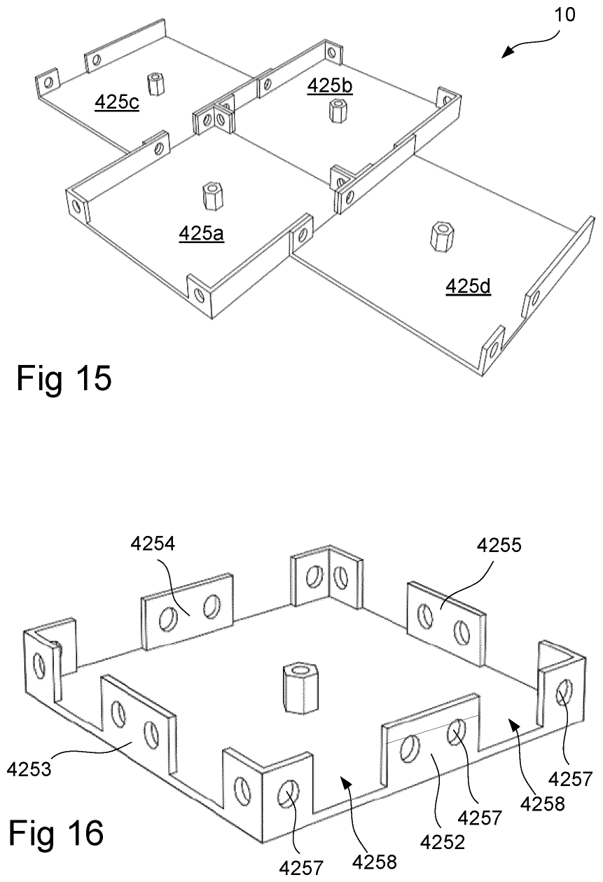

Referring to FIG. 15, there is illustrated another way of forming a base module 10, wherein first and second lower parts 425a, 425b formed as illustrated in FIG. 7 connected open side to open side.

Third and fourth lower parts 425c, 425d formed as illustrated in FIG. 6 are connected with their walled sides to the walled sides of the first and second lower parts 425a, 425b and with openings of the third and fourth lower parts 425c, 425d aligned with openings of the first lower part 425a.

The lower parts 425a, 425b, 425c, 425d may be interconnected by connectors as illustrated with reference to FIG. 8. An integrated upper part (not shown) may be arranged to cover all of the lower parts 425a, 425b, 425c, 425d analogous with what was illustrated in FIGS. 9 and 10.

Alternatively an upper part may be provided covering the first and second lower parts 425a, 425b, while normal upper parts may be provided for the third and fourth lower parts 425c, 425d.

Referring to FIG. 16, there is illustrated another version of a lower part 425, wherein each of the side walls 4252, 4253, 4254, 4255 has two openings 4258, which are laterally offset from a lateral center C of the respective side wall.

Moreover, in FIG. 16, each side wall 4252, 4253, 4254, 4255 comprises a pair of corner portions, extending from a respective end of edge so as to accommodate a engagement portion 4257, and a central portion, which is laterally spaced from the corner portions by the openings 4258 and which accommodates at least one engagement portion 4257.

In the illustrated embodiment, the corner portions of the side walls may each extend along about 10-15% of an edge length.

The openings 4258 may each extend along about 20-25% of an edge length.

The central portion may extend along about 25-30% of the edge length. The openings 4258 may, but need not, extend along an entire side wall height.

The lower part 425 illustrated in FIG. 16 may be formed with flanges as illustrated in FIG. 3 and/or with a central protrusion as illustrated in FIG. 4.

It is possible to increase a weight of one or more transfer modules 42 and/or of a base module 10 by providing one or more sheet metal pieces (not illustrated) at a bottom of the base module, so as to act as additional weights.

Alternatively, or as a supplement, it is possible to fill a transfer module 42 or a base module with sand or gravel to give it extra weight.

The central protrusion which is illustrated in e.g. FIG. 4 may be used additionally, or exclusively, as a support for the central portion of the upper part 426, so as to reduce deformation of the upper part 426 when it is subjected to a high load. Hence, the central protrusion may have a heigh that corresponds to a height of the side walls. Also, the central protrusion need not provide any fastening device.

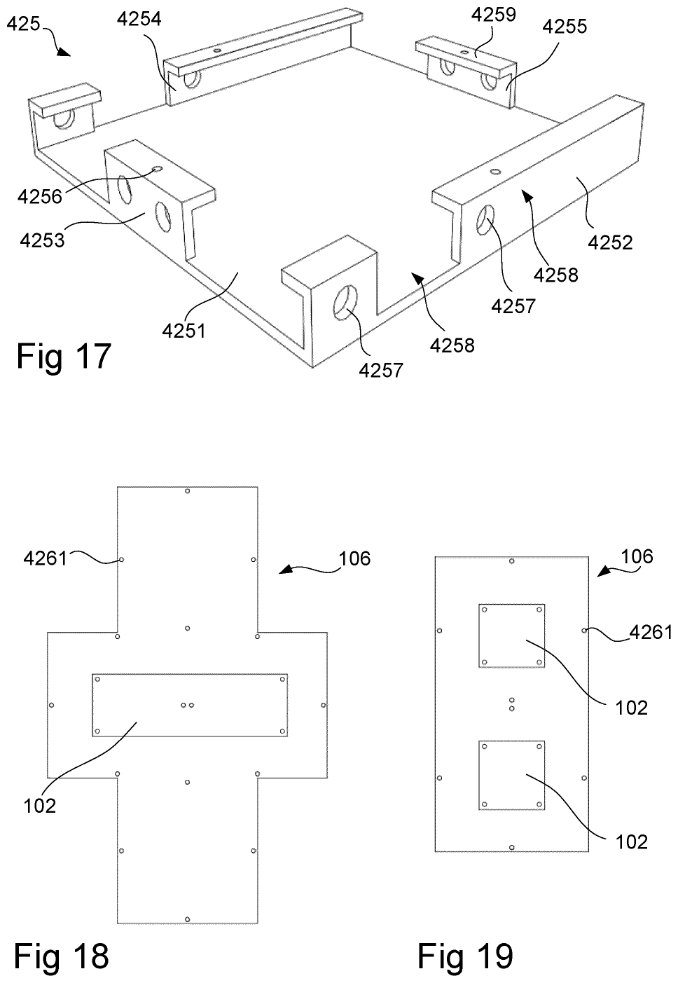

FIG. 17 schematically illustrates yet another version of a lower part 425, which has a bottom 4251 and four side walls 4252, 4253, 4254, 4255.

First and second opposite side walls 4252, 4254 extend along an entire respective opposite edge, except for openings 4258, which are aligned. The first and second side walls 4252, 4254 each comprise a first portion, which is arranged at a first edge end and which has a width that is sufficient to provide space for an engagement portion 4257 and a second portion, which has a width that is slightly more than ½ of an edge length.

Third and fourth opposite side walls 4253, 4255 extend along a portion of their respective edges and are perpendicular to the first and second opposite side walls 4252, 4254. The third and fourth opposite side walls 4253, 4255 are spaced from edge ends, such that they do not meet the first and/or second side walls 4252, 4254.

At least one of the side walls 4252, 4253, 4254, 4255 may present a flange 4259, which may present a fastening device 4256.

Alternatively, the lower part 425 illustrated in FIG. 17 may be designed without flanges 4259, and instead with a centrally arranged protrusion that may house the fastening device, e.g. as illustrated in FIGS. 4, 5, 6, 7 and 16. FIG. 18 schematically illustrates yet another version of an upper part 426 for a composite base module, such as the one illustrated in FIG. 15. Hence, the upper part 426 may be designed such that it covers four lower parts, such that it has the general shape of a cross. The upper part 426 may have at least one opening 102 or adapter, for attachment of an outlet 12 or of an outlet pole 10 and one or more fastening devices 4261 for attachment to lower parts 425 and/or base parts. FIG. 19 schematically illustrates yet another version of an upper part 426 for a composite base module. This upper part 426 may be formed as a rectangular part with one or more openings 102 or adapters, for attachment of an outlet 12 or of an outlet pole 10 and one or more fastening devices 4261 for attachment to lower parts 425 and/or base parts.

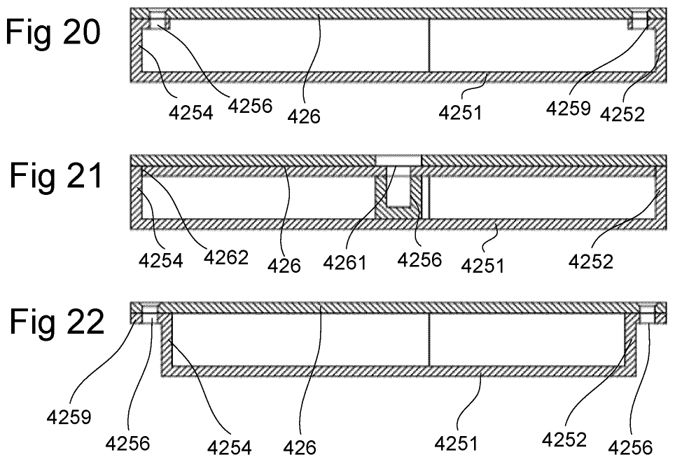

FIG. 20 schematically illustrates a transfer module designed generally in accordance with FIGS. 3 and 17, with side walls 4252, 4254 having inwardly bent flanges 4259 configured to accommodate fastening devices 4256.

FIG. 21 schematically illustrates a transfer module designed generally in accordance with FIGS. 4-7 and 15-16, with side walls 4252, 4254 having no flanges and instead with a centrally located fastening device 4261, 4256.

FIG. 22 schematically illustrates an alternative transfer module designed generally in accordance with FIGS. 3 and 17, but with flanges 4259 bent outwardly instead of inwardly, as in FIG. 20.

It is possible to combine e.g. one pair of opposing side walls designed in accordance with FIG. 20 with another pair of opposing side walls designed in accordance with FIG. 21 or FIG. 22. Optionally, a centrally located fastening device 4256 may be combined with flanges in accordance with FIG. 20 or FIG. 22.

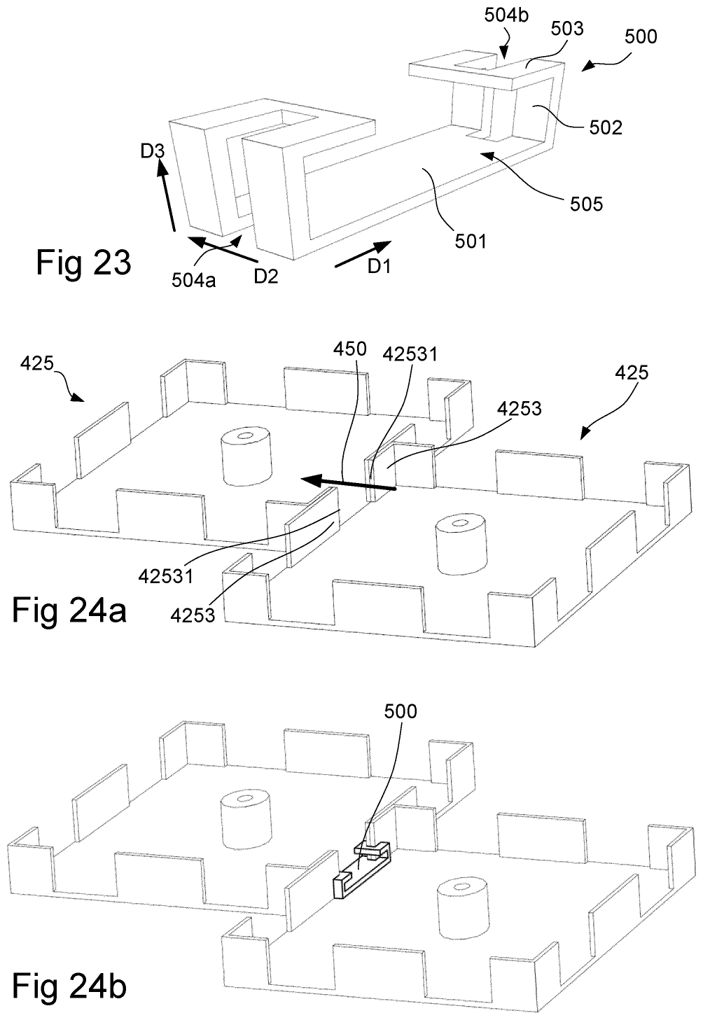

FIG. 23 is a schematic perspective view of a connecting element 500 for mechanically connecting a pair of adjacent transfer module lower parts 425.

The connecting element 500 of FIG. 23 comprises an element body 501, 502, 503, presenting a pair of opposing side surfaces, a first groove 504a formed in a first one of the side surfaces and a second groove 504b formed in a second one of the side surfaces. The first and second grooves 504a, 504b present a respective length direction, which are parallel with each other.

The element body has a first direction D1 extending between the opposing side surfaces, a second direction D2 which extends perpendicular to the groove length direction and a third direction D3 which is parallel with the groove length direction.

The grooves 504a, 504b may be straight and present a respective groove length direction, which may be parallel with the third direction D3, a groove depth direction which may be parallel with the first direction D1 and a groove width direction which may be parallel with the second direction D2.

The element body may comprise a first wall portion 501 extending along the first and second directions D1, D2, with a thickness direction extending along the third direction D3.

The element body may comprise a pair of second wall portions 502, extending along the second and third directions D2, D3, with a thickness direction extending along the first direction D1.

In the embodiment illustrated in FIG. 23, the element body presents a pair of third wall portions 503, extending along the first and second directions D1, D2, with a thickness direction extending along the third direction D3.

The first and third wall portions 501, 503 may be parallel with each other. The second wall portion 502 may be perpendicular to the first and/or third wall portions 501, 503.

The grooves 504a, 504b may, but need not, extend through the entire thickness of the second wall portion 502.

The element body 501, 502, 503 may have a generally cubic or cuboid shape. However, corners may be more or less rounded or beveled.

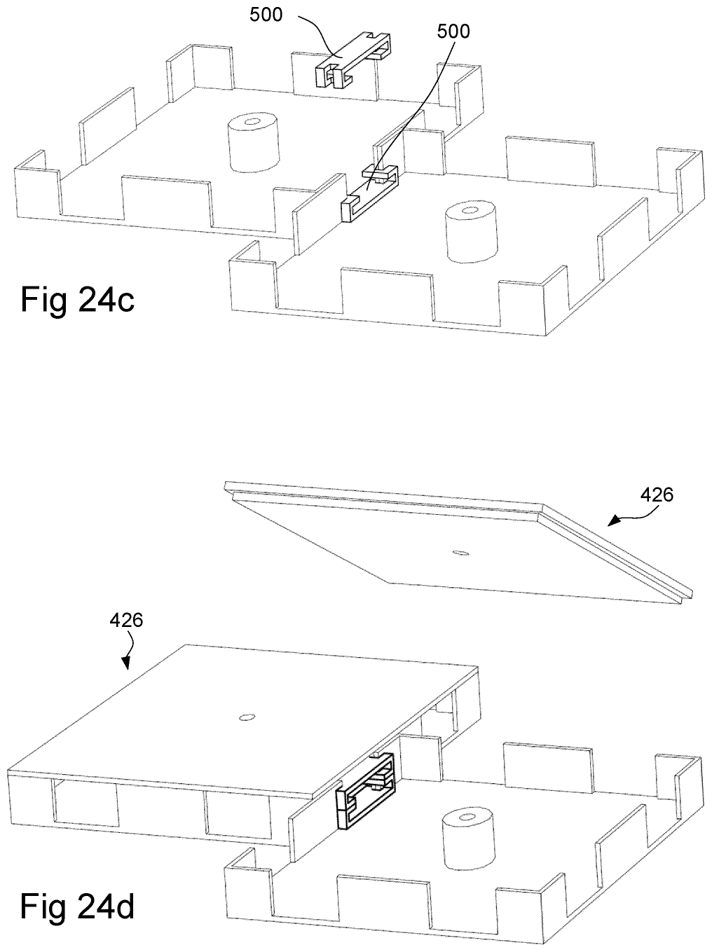

FIGS. 24a-24d schematically illustrate a method of mechanically connecting a pair of adjacent transfer module lower parts 425. In FIGS. 24a-24d, a joint plane is defined as a vertical plane that is parallel with the side walls 4253 that are to be connected.

Referring to FIGS. 24a-24d, the connecting element 500 is intended for use to interconnect side walls 4253 of adjacent transfer modules 42, when the transfer modules 42 are positioned in a common plane and a laterally open opening 4258 of a first one of the transfer module lower parts 425 is aligned with a laterally open opening 4258 of a second one of the transfer modules, such that the openings 4258 form a channel 450 connecting an interior of the one of the transfer modules with an interior of the second one of the transfer modules. The channel 450 will be laterally limited by vertically extending wall edge portions 42531 of the side walls 4253, as illustrated in FIG. 24a. The wall edge portions 42531 are arranged on horizontally opposite sides of the channel 450, when the transfer module lower parts 425 are arranged on a horizontal surface. Hence, on each lateral side of the channel 450, there is a pair of aligned wall edge portions 42531 provided, each forming part of a respective one of the transfer module lower parts 425 to be connected.

As illustrated in FIG. 24b, a connecting element 500 has been applied to the opening 4258 forming the channel 450 by each pair of aligned wall edge portions 42531 being received in a respective one of the first and second grooves 504a, 504b, such that relative movement between the transfer module lower parts 425 is prevented in the direction perpendicular to the joint plane and in a horizontal direction in the joint plane.

Also as illustrated in FIG. 24b, there is used a connecting first element 500 that has a height in the third direction which corresponds to about half of a height of the channel 450.

As is illustrated in FIG. 24c, there is used a second connecting element 500, which may, but need not, be identical to the first connecting element 500.

As illustrated in FIG. 24c, the first connecting element may be arranged such that it provides an opening that is downwardly limited by the first portion 501 of the element body, while the second connecting element may be arranged such that it provides an opening that is upwardly limited by the first portion 501 of the element body.

In FIG. 24d, there is illustrated how the provision of upper parts 426, in the manner described above, will lock the connecting element(s) 500 in place, such that vertical relative movement between the transfer module lower parts 425 is prevented.

It is understood that the grooves 504a, 504b may be designed in various ways.

In some embodiments, in particular where the connecting element 500 is effectively rigid, it may be desirable to allow some play along at least one of the directions D1, D2, D3, to allow for tolerances, minor misalignment of the transfer module lower parts 425 and/or for such movements as may be expected in the relevant type of installation. Such play may, but need not, be supplemented by the provision of one or more elastic compounds or elastic elements that may provide sealing and/or prevent the connecting element 500 from causing noise when moving relative to the transfer module lower parts 425.

Such elastic compound or elastic element may be applied in connection with the production of the connecting element 500 or in connection with its installation or preparation for installation.

Consequently, a groove width may be at least double a side wall thickness of the transfer module lower parts 425. The groove width may also be adapted to accommodate any space which may be present between the side walls that are to be connected, such as a joint spacing that is to be filled with a joint material, such as sand, grout, or the like.

Alternatively, the grooves 504a, 504b may be provided as a pair of spaced-apart sub-grooves, adapted for engaging a respective one of the adjacent side wall edge portions 42531, such that a predetermined joint spacing between the transfer module lower parts 425 will be maintained by the connecting element 500.

The connecting element 500 may also provide a protection for cables drawn through the cable channel 450. Hence, the cables may be protected from being scraped or cut by edges limiting the opening 4258.

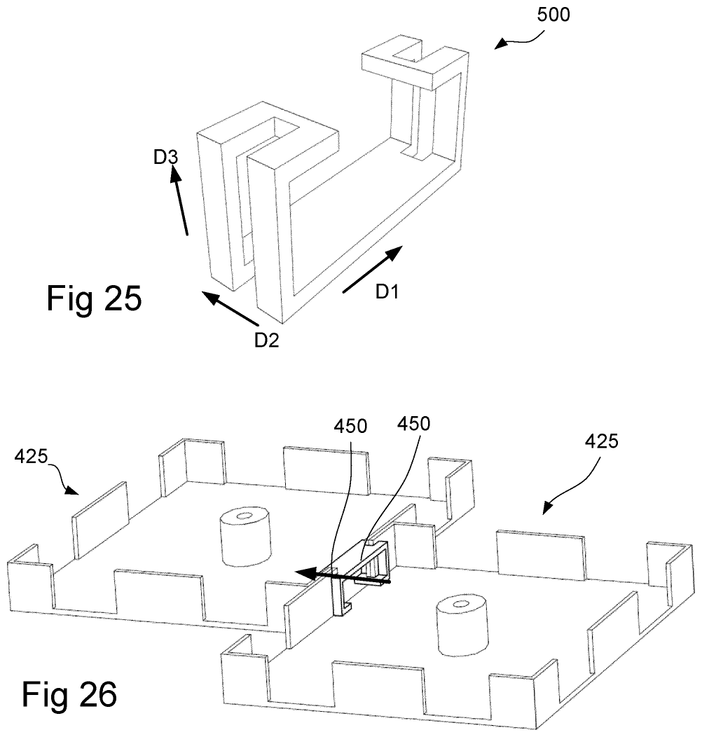

FIG. 25 is a schematic perspective view of a first alternative design of the connecting element.

This alternative design of the connecting element 500 differs from the one illustrated in FIG. 23 in that the second wall portions 502 have a greater extent in the third direction D3, such that the connecting element 500 has a height which corresponds to about the full height of the channel 450, such that only one connecting element 450 need be provided, as illustrated in FIG. 26, which schematically illustrates the connecting element according to the first alternative design in a state where it mechanically connects a pair of adjacent transfer modules.

The connecting element 500 illustrated in FIGS. 23-26 may be produced by casting/molding, or by bending and cutting a sheet-shaped substrate. In the latter case, the first, second and third wall portions 501, 502, 503 may have the same thickness.

The connecting element 500 may be formed from a material that is essentially rigid, such as metal, in particular sheet metal and/or cast iron.

Alternatively, the connecting element 500 may be formed from a material that is elastic, such as engineering plastics, thermoplastic elastomers, rubber, silicone, or the like.

A connecting element formed of a more rigid material may be provided with cutouts so as to allow some deformation without rupture.

It is conceivable to provide a connecting element formed of two or more materials, such as a rigid core (metal or plastic) core with more elastic portions or coating.

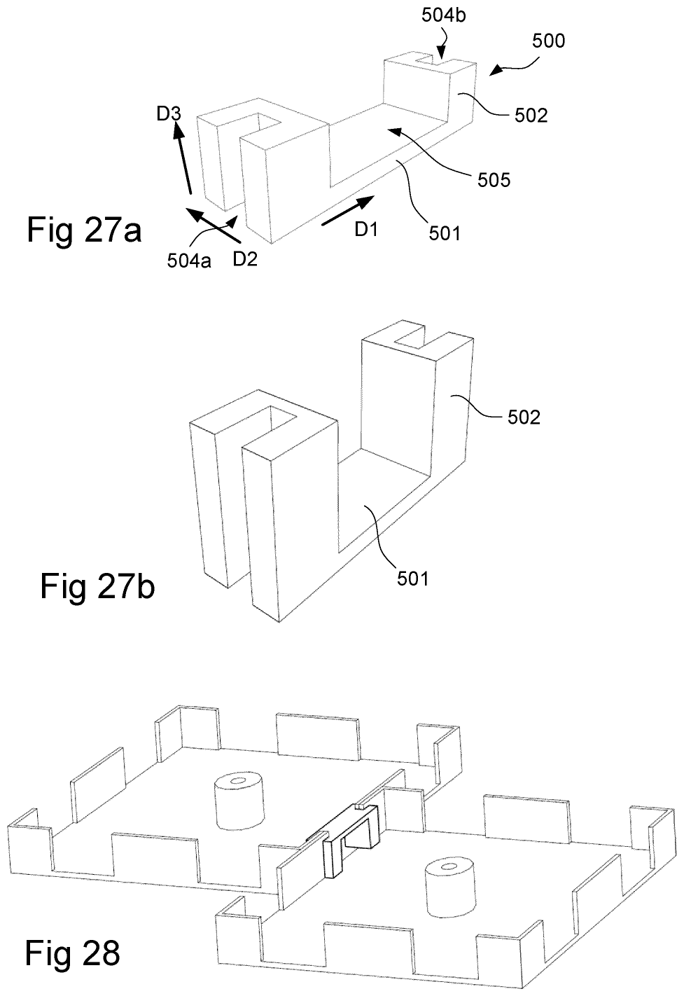

FIGS. 27a and 27b are schematic perspective views of connecting elements 500 according to second and third alternative designs, which may be suitable for production by casting and/or molding.

In particular, the first wall portion 501 of the element body may extend along the first and second directions D1, D2, with a thickness direction extending along the third direction D3.

The second wall portions 502, may along the second and third directions D2, D3, with a thickness direction extending along the first direction D1.

A thickness of the second wall portions 502 may be greater than a thickness of the first wall portion 501.

The grooves 504a, 504b may be formed in the second wall portions and have a groove depth that is less than the thickness of the second wall portion 502.

FIG. 27a illustrates a connecting element 500 having the same height and use as the one illustrated in FIG. 23.

FIG. 27b illustrates a connecting element 500 having the same height and use as the one illustrated in FIG. 25.

FIG. 28 schematically illustrates the connecting element 500 according to the third alternative design in a state where it mechanically connects a pair of adjacent transfer module lower parts 425.

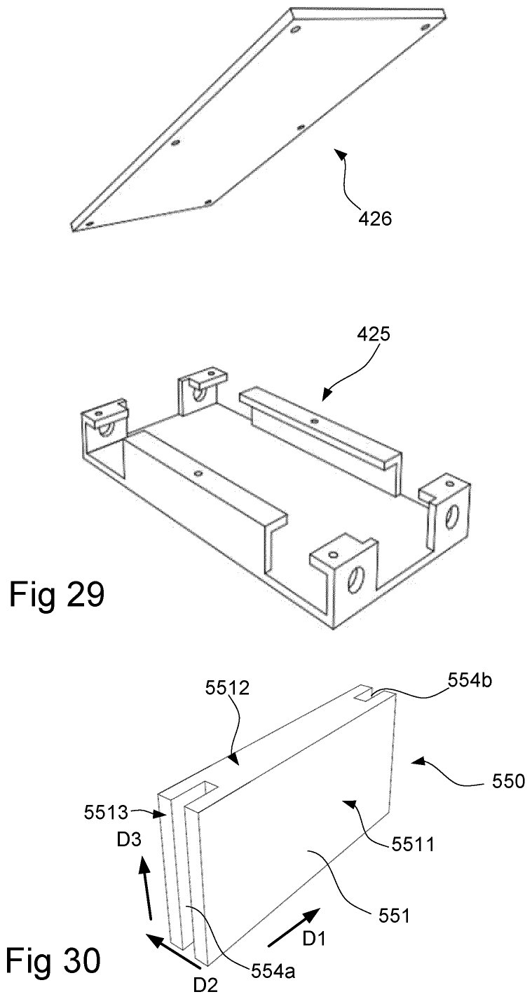

FIG. 29 schematically illustrates a transfer module, comprising a lower part 425 and an upper part 426, in the form of a “half tile”. Such half tile would have a first side that has the same length as a standard tile, e.g. 35 cm and a second side, perpendicular to the first side, that has a length which is about 50% of the length of the first side.

FIG. 30 schematically illustrates a spacer element 550, which may be used to provide a lateral spacer towards adjacent transfer modules 42 and/or pavement stones. Depending on the design, the spacer element 550 may also be used as a blind element in order to close side wall openings 4258 in the event it is desired to prevent or reduce ingress of water, joint filler and/or debris.

The spacer element 550 may comprise a spacer element body 551, which may be essentially planar, with a first pair of opposing sides 5511 extending in directions D1 and D3, a second pair of opposing sides 5512 extending in directions D1 and D2 and a third pair of opposing sides 5513 extending in directions D2 and D3, as illustrated in FIG. 30.

The first sides 5511 may form a main face of the spacer element 550.

The second sides 5512 may form a thickness of the spacer element 550.

The second pair of opposing sides 5513 present a first groove 554a formed in a first one of the opposing sides 5513 and a second groove 554b formed in a second one of the opposing sides 5513. The first and second grooves 554a, 554b present a respective length direction, which are parallel with each other.

The spacer element body 551 thus has a first direction D1 extending between the opposing side surfaces, a second direction D2 which extends perpendicular to the groove length direction and a third direction D3 which is parallel with the groove length direction.

The grooves 554a, 554b may be straight and present a respective groove length direction, which may be parallel with the third direction D3, a groove depth direction which may be parallel with the first direction D1 and a groove width direction which may be parallel with the second direction D2.

A groove width may approximately correspond to a wall thickness of wall edge portions 42531 that are to engage with the grooves 554a, 554b.

In some embodiments, the spacer element body 551 may have a thickness in the D2 direction that will cause the spacer element body 551 to protrude outside of the side wall 4253 to such an extent as to provide a desired lateral spacing between the transfer module lower part 425 and an adjacent transfer module lower part or an adjacent pavement stone.

In other embodiments, the spacer element body may be thinner than required, but provided with one or more protrusions which may provide the desired lateral spacing effect. Such protrusions may be provided as one or more ridges or hills on a main face 5511 of the spacer element 550.

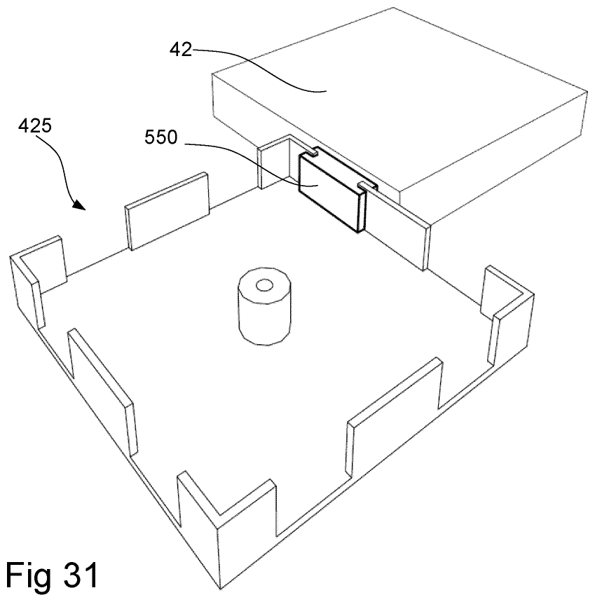

FIG. 31 schematically illustrates a transfer module lower part 425 installed adjacent a pavement stone 41, with a spacer element 550 provided in a side wall opening 4253.

1-40. (canceled)

41. A method of installing an electrical outlet for charging an electric vehicle at a curb, wherein the curb is spaced by a sidewalk from a power supply at a house façade, the method comprising:
providing the power supply at the house façade,
providing the outlet at the curb, and
connecting a power supply cable from the power supply to the outlet,
wherein the sidewalk presents a surfacing formed of a plurality of pavement stones,
the power supply cable is installed in a cable channel extending from the power supply to the curb and provided in a plurality of transfer modules, which have a thickness that is approximately the same as a thickness of the pavement stones and which are installed in a same plane as the pavement stones.

42. The method as claimed in claim 41, wherein the outlet is provided at a first position along the curb, the method further comprising:
providing a second outlet at a second position along the curb, spaced from the first position,
arranging a plurality of curb modules laterally outside the curb, such that the curb modules extend between the first position and the second position, and
installing a second power supply cable is in a cable channel, which extends between the first position and the second position and which is provided in said curb modules.

43. The method as claimed in claim 41, wherein at least one of a length of the transfer modules and a width of the transfer modules corresponds to at least one of a length of the pavement stones and a width of the pavement stones.

44. The method as claimed in claim 41, wherein the pavement stones and the transfer modules are installed on a bed of sand, preferably compacted sand.

45. The method as claimed in claim 41, wherein a lower surface of the pavement stones is coplanar with a lower surface of the transfer modules.

46. The method as claimed in claim 41, wherein the cable channels are spaced from both a transfer module upper surface and a transfer module lower surface.

47. The method as claimed in claim 41, wherein each transfer module comprises at least one pair of parallel and equally long opposing side walls, wherein the cable channel is laterally spaced from a lateral center of each of said opposing side walls.

48. The method as claimed in claim 41, wherein said side walls present a connector, such as recess or through hole, which allows for an interconnection with an side wall of an immediately adjacent transfer module.

49. The method as claimed in claim 41, wherein the transfer modules are hollow.

50. The method as claimed in claim 41, wherein the pavement stones are formed of natural stone, cement or a composite thereof.

51. The method as claimed in any claim 41, wherein the transfer modules are formed of a metal material, such as iron, steel or aluminum.

52. A transfer module, comprising:
a lower part having a bottom and at least two side walls, extending essentially perpendicular from respective edge portions of the bottom, so as to define an upwardly open receptacle, and
an upper part, which is connectable to the lower part and which is sized and adapted to cover the receptacle,
wherein the lower part presents at least one laterally open opening, which is sized and adapted for receiving a power cable.

53. The transfer module as claimed in claim 52, further comprising a fastening device, for releasably fastening the upper part to the lower part.

54. The transfer module as claimed in claim 52, wherein at least one of the side walls comprises an engagement portion, for releasably interconnecting the lower part to another, identical or similar, lower part.

55. The transfer module as claimed in claim 52, wherein at least one of the side walls has a flange provided at a distal portion of the side wall.

56. The transfer module as claimed in claim 52, wherein the transfer module has a total thickness, when the upper part is connected to the lower part, which thickness is the same as a standard thickness of a pavement stone of concrete or natural stone.

57. The transfer module as claimed in claim 52, wherein the transfer module is rectangular and has a greatest length which is the same as a standard length of a pavement stone of concrete or natural stone.

58. A power supply installation, comprising:
an electrical outlet,
a power supply, and
a plurality of transfer modules as claimed in claim 52, arranged coplanarly with a surfacing covering an area, and
a cable arranged in a cable channel provided in said transfer modules and extending from the power supply to the electrical outlet.

59. A method of installing an electrical outlet at a surface having a surfacing, the method comprising:
providing at least two transfer modules as claimed in claim 52,
removing the surfacing in an area having a width corresponding to a transfer module width and a length corresponding to a distance from a power source to the outlet,
arranging the transfer modules in said area, such that the openings of the transfer modules align to form a cable channel.

60. The method as claimed in claim 59, wherein:
the surfacing is formed of a plurality of pavement stones,
said removing comprises removing the pavement stones to be replaced by the transfer modules, and
said arranging comprises arranging the transfer modules coplanarly with the pavement stones.
